(19) United States
(12) Patent Application Publication
(10) Pub. No.: US 2006/0050903 A1
(43) Pub. Date: Mar. 9, 2006

(54) Waterproof audio player

(75) Inventor: Raymond Chan, Hong Kong (HK)

Correspondence Address: LEYDIG VOIT & MAYER, LTD, 700 THIRTEENTH ST. NW, SUITE 300, WASHINGTON, DC, 20005-3960, US

(73) Assignee: IDT Data System Limited, Hunghom (HK)

(21) Appl. No.: 10/934,744

(22) Filed: Sep. 7, 2004

(51) Int. Cl. G09F 27/00

(52) U.S. Cl. 381/124; 206/811; 381/87

(57) ABSTRACT

A waterproof audio player comprises a body having a casing and a lid closing the casing in a sealed manner, the casing and the lid including respective inner walls confronting each other. An audio playing module in the casing includes a phone jack located on the inner wall of the casing. There is also an earphone including an electrical plug fixed inside the lid. The plug has an electrical connector which projects from the inner wall of the lid and is aligned with the phone jack for insertion into the phone jack upon the lid closing the casing.

The subject invention relates to an audio player and particularly but not exclusively to an MP3 player with FM radio, which is waterproof or splash-proof.

### BACKGROUND OF THE INVENTION

Audio players that are waterproof or splash-proof are not new, which normally utilize earphones instead of built-in speakers for audio output as speakers are vulnerable to damage by water and/or are difficult to protect. Such earphones are usually permanently wired to avoid a loose connection that is leakage-prone and this hampers output flexibility.

The invention seeks to obviate or at least alleviate such a shortcoming by providing a new or improved waterproof audio player.

### SUMMARY OF THE INVENTION

According to the invention, there is provided a waterproof audio player comprising:
a body having a casing and a lid closing the casing in a sealed manner, the casing and the lid including respective inner walls confronting each other;
an audio playing module provided in the casing, which includes a phone jack located on the inner wall of the casing;
an earphone including an electrical plug fixed inside the lid, the plug having an electrical connector projecting from the inner wall of the lid and aligned with the phone jack for insertion into the phone jack upon the lid closing the casing.

Preferably, at least one of the casing and the lid includes resilient material around its inner wall for sealing engagement with the inner wall of the other of the casing and the lid.

It is preferred that the earphone includes an electric cable connected to the plug and extending out from inside the lid, with a seal provided between the cable and the lid.

It is further preferred that the seal comprises glue.

Preferably, the electrical plug includes a base having a first end from which the electrical connector projects through the inner wall of the lid and an opposite second end located by an internal fixture of the lid.

In a preferred embodiment, the waterproof audio player includes a securing member which extends through the lid and engages with a part of the casing to thereby secure the lid closing the casing.

More preferably, the securing member comprises a screw or bolt and the part of the casing comprises a nut.

It is preferred that the lid has a central axis along which the screw or bolt extends.

It is preferred that the securing member extends substantially parallel to the electrical connector.

Preferably, the audio playing module includes an input port provided on the inner wall of the casing.

More preferably, the input port comprises a USB socket.

It is preferred that the lid is detachable from the casing.

As an example, the audio playing module comprises an MP3 playing module.

### BRIEF DESCRIPTION OF DRAWINGS

The invention will now be more particularly described, by way of example only, with reference to the accompanying drawings, in which:

FIG. 1 is a front view of an embodiment of an audio player in accordance with the invention;

FIG. 2 is a cross-sectional right side view of the audio player of FIG. 1, taken along line II-II;

FIG. 3 is a left side view of the audio player of FIG. 1;

FIG. 4 is a cross-sectional rear view of the audio player of FIG. 3, taken along line IV-IV;

FIG. 5 is a top plan view of the audio player of FIG. 1;

FIG. 6 is a bottom plan view of the audio player of FIG. 1;

FIG. 7 is a rear view of the audio player of FIG. 1;

FIG. 8 is a front view of the audio player of FIG. 1, with two parts thereof shown separated; and

FIG. 9 is a cross-sectional rear view of the audio player of FIG. 8.

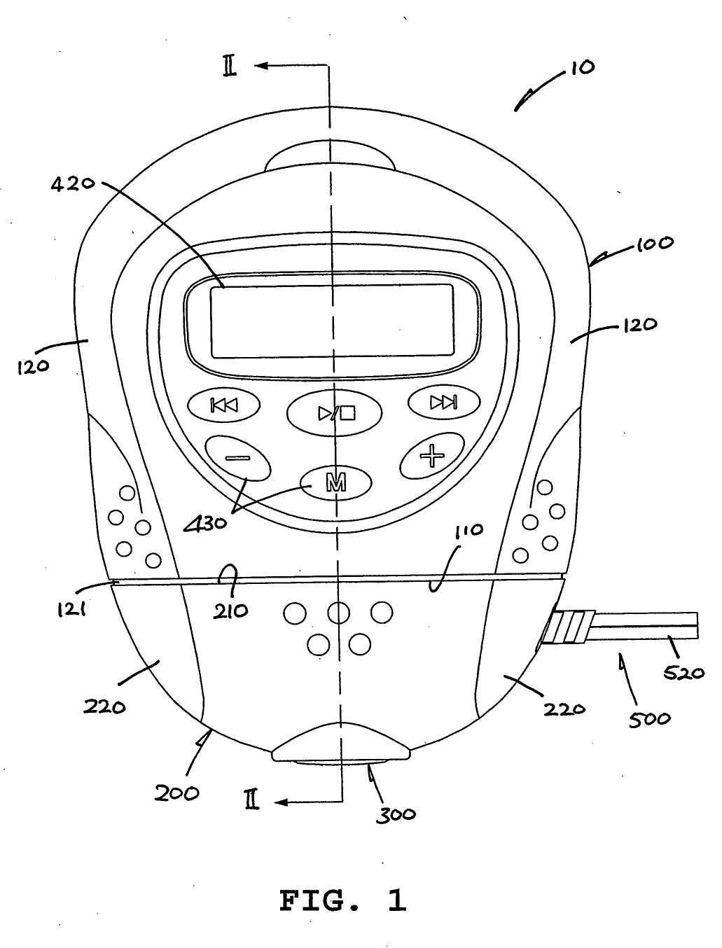

### DETAILED DESCRIPTION OF PREFERRED EMBODIMENT

Referring to the drawings, there is shown a waterproof audio player in the form of a portable MP3 player 10 embodying the invention, which has a flat oval body formed by a casing 100 and a separate bottom lid 200 closing the casing 100. The casing 100 and the lid 200 include, as between them, respective horizontal generally flat inner walls 110 and 210 confronting each other while the lid 200 closes the casing 100.

The casing 100, which is primarily molded from a hard plastics material, includes a relatively thick coating 120 of a resilient rubber material applied thereon by an insert molding operation for example. The coating 120 extends over the complete periphery of the casing 100 including a bottom portion 121 around its inner wall 110, which acts as a seal ring for sealing engagement with the inner wall 210 of the lid 200. Similarly, the lid 200 is molded from a hard plastics material and includes an insert molded coating 220 of the same rubber material on opposite left and right sides thereof matching the casing coating 120. Apart from providing the seal 121, the rubber coatings 120 and 220 serve to facilitate gripping of the MP3 player 10 by hand.

The lid 200 has a vertical central axis and incorporates an upright screw or bolt 300 which extends along the axis through the lid 200 from below, having a lower head 301 and an upper screw-threaded end 302. There is a nut 310 mounted centrally at the inner wall 110 of the casing 100 for engagement by the bolt 300. While closing the casing 100, the lid 200 is attached and secured in place upon tightening the bolt 300 through the nut 310, whereby the lid 200 is pressed against the casing 100 and the two parts are sealed together. The outer walls of the casing 100 and the lid 200 including all the features thereon are made watertight and this, in conjunction with the sealing engagement between the casing 100 and the lid 200, renders the overall MP3 player 10 at least splash-proof or in the case of the described embodiment waterproof to one meter depth of water.

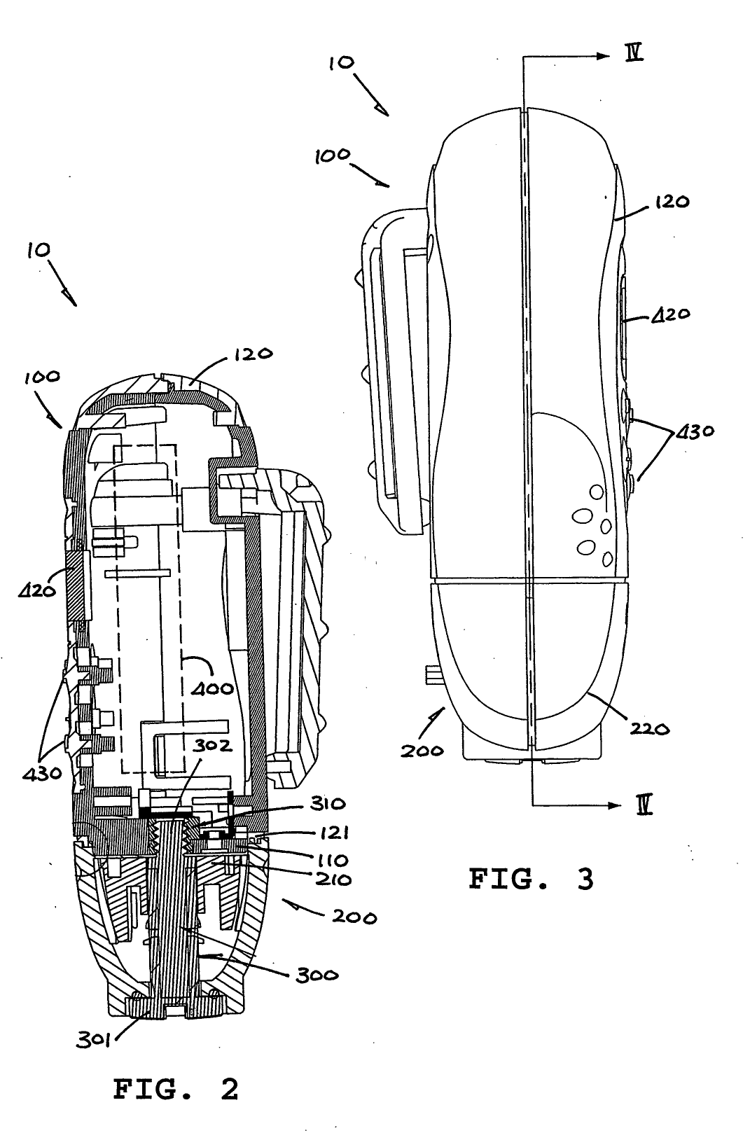

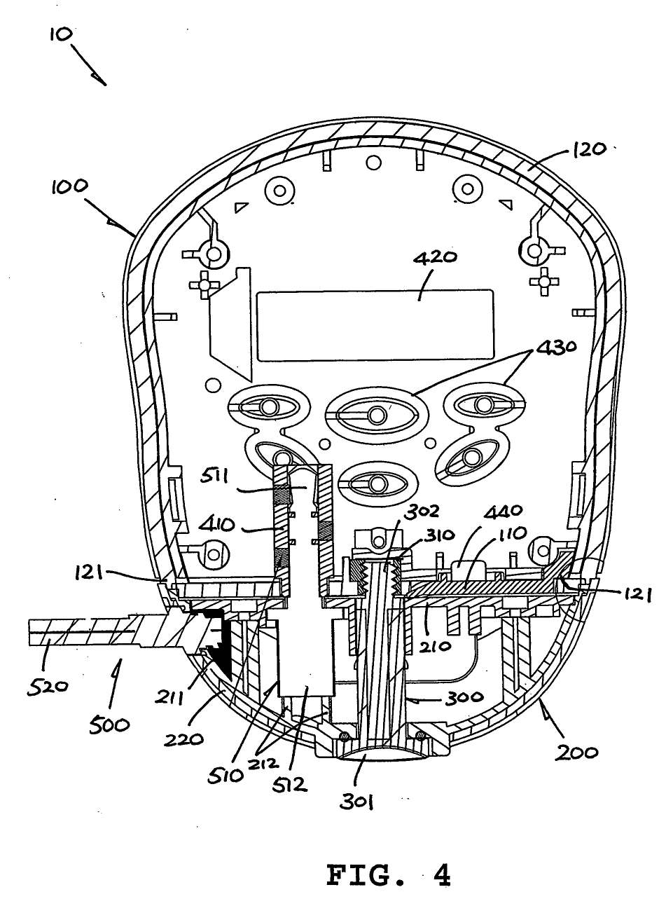

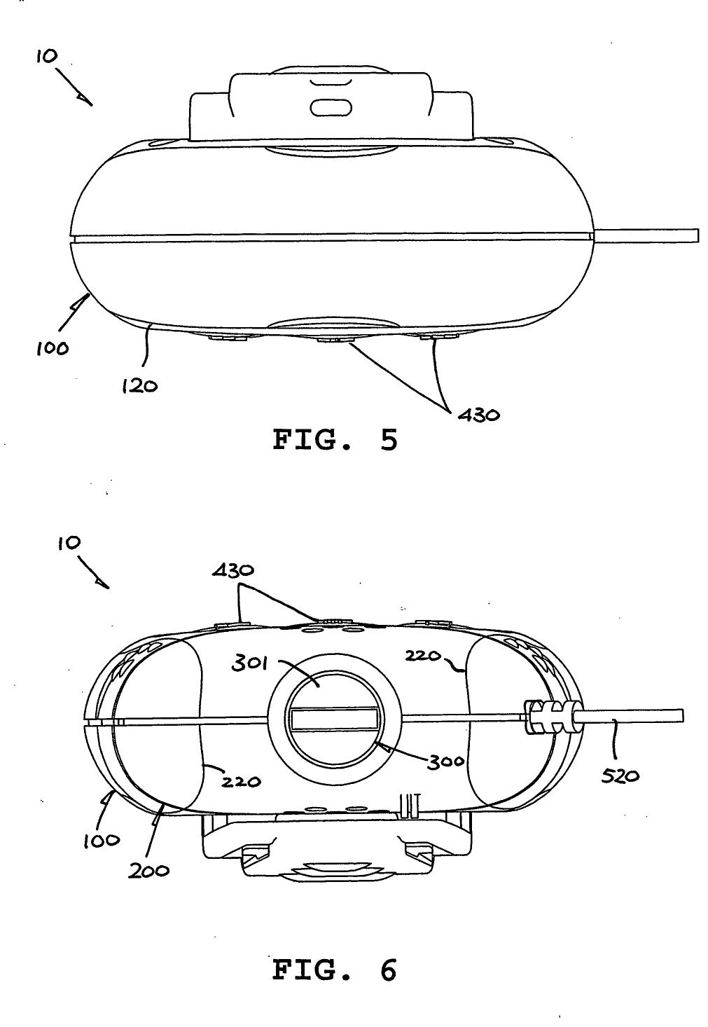

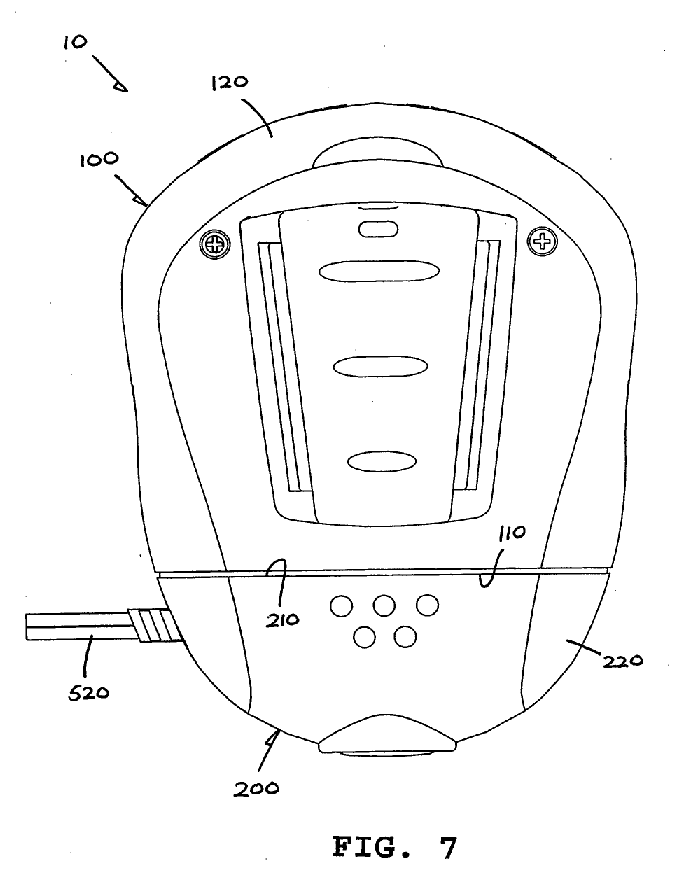

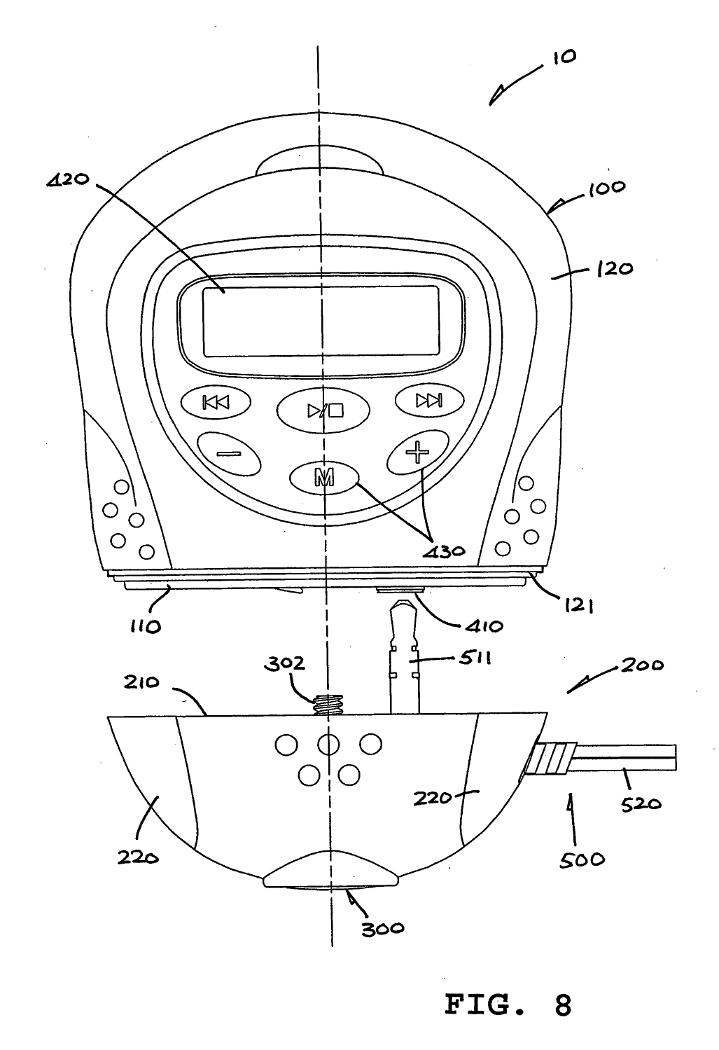

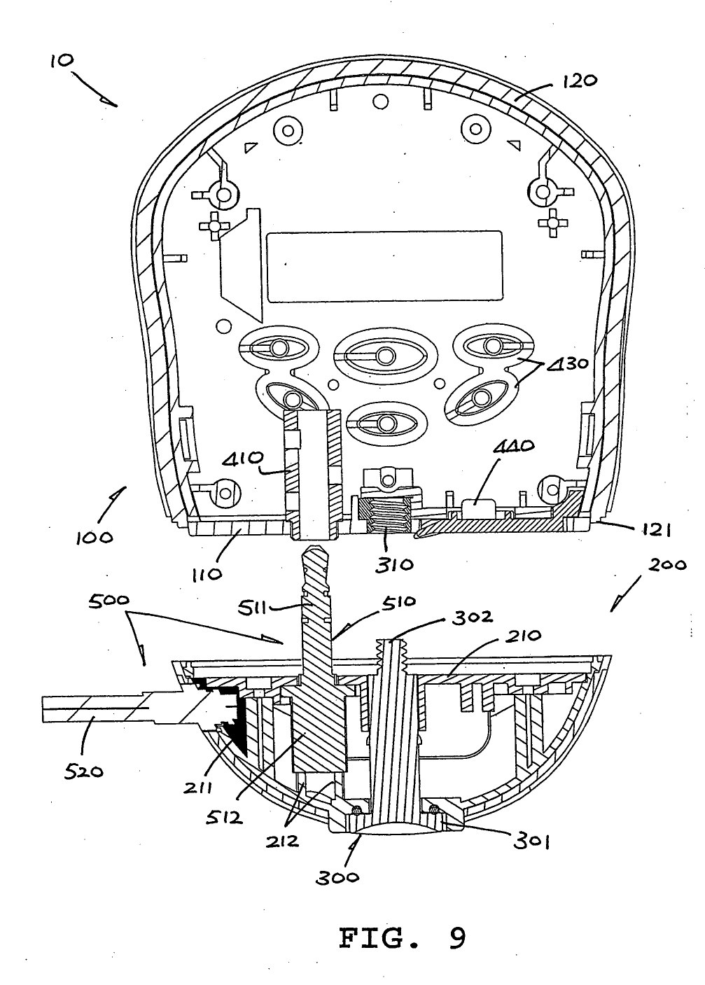

The casing 100 houses an MP3 playing module 400 (only schematically depicted in FIG. 2) which includes a Ø3.5 mm phone jack 410 mounted on the inner wall 110 adjacent the nut 310 for audio output. The playing module 400 is connected to an LCD display 420 and a number of press keys 430 on the front surface for operation. Also mounted on the inner wall 110 is a USB socket 440 on the other side of the nut 310 as an input port for loading MP3 data. There is further a built-in EM radio tuner. All these constitute a main unit of the MP3 player 10.

The MP3 player 10 incorporates an integrated earphone 500 which includes an electrical plug 510 fixed inside the lid 200. An electric cable 520 connected to the plug 510 leading to a pair of ear-mounted speakers (not shown) extends out from inside the lid 200, which is sealed at a position just before leaving the lid 200 by glue 211 against water ingress.

The plug 510 has a Ø3.5 mm electrical connector 511 and a base 512 from an upper end of which the connector 511 extends co-axially upright. The base 512 is located wholly within a cavity of the lid 200, in that the cavity has a bottom defined by an internal fixture 212 which supports the lower end of the base 512. The connector 511 projects upwardly, at right angles, through the inner wall 210 of the lid 200. The plug 510 is positioned aligning with the phone jack 410 such that closing of the lid 200 upon the casing 100 brings about insertion of the connector 511 into the jack 410 whereby the earphone 500 is connected at the same time.

The lid 200 may be opened or detached by loosening the bolt 300. Removal of the lid 200 reveals the phone jack 410 on the casing 100, and this permits the use of another earphone or connection of the main unit to an amplifier or a pair of active speakers for example. The USB socket 440 is also revealed for loading of MP3 data. It is noted that the main unit can operate without the lid 200 and earphone 500.

The invention has been given by way of example only, and various modification of and/or alterations to the described embodiment may be made by persons skilled in the art without departing from the scope of the invention as specified in the appended claims.

1. A waterproof audio player comprising:
a body having a casing and a lid closing the casing in a sealed manner, the casing and the lid including respective inner walls confronting each other;
an audio playing module located in the casing, and a phone jack located on the inner wall of the casing; and
an earphone including an electrical plug fixed inside the lid, the plug having an electrical connector projecting from the inner wall of the lid and aligned with the phone jack for insertion into the phone jack upon closing of the lid onto the casing.

2. The waterproof audio player as claimed in claim 1, wherein at least one of the casing and the lid includes resilient material around its inner wall for sealing engagement with the inner wall of the other of the casing and the lid.

3. The waterproof audio player as claimed in claim 1, wherein the earphone includes an electric cable connected to the plug and extending out from inside the lid, with a seal located between the cable and the lid.

4. The waterproof audio player as claimed in claim 3, wherein the seal comprises glue.

5. The waterproof audio player as claimed in claim 1, wherein the electrical plug includes a base having a first end from which the electrical connector projects through the inner wall of the lid and a second end located by an internal fixture of the lid.

6. The waterproof audio player as claimed in claim 1, including a securing member which extends through the lid and engages a part of the casing to secure the lid when closing the casing.

7. The waterproof audio player as claimed in claim 6, wherein the securing member comprises one of a screw and a bolt and the part of the casing comprises a nut.

8. The waterproof audio player as claimed in claim 6, wherein the lid has a central axis along which the securing member extends.

9. The waterproof audio player as claimed in claim 6, wherein the securing member extends substantially parallel to the electrical connector.

10. The waterproof audio player as claimed in claim 1, wherein the audio playing module includes an input port located on the inner wall of the casing.

11. The waterproof audio player as claimed in claim 10, wherein the input port comprises a USB socket.

12. The waterproof audio player as claimed in claim 1, wherein the lid is detachable from the casing.

13. The waterproof audio player as claimed in claim 1, wherein the audio playing module comprises an MP3 playing module.

14. The waterproof audio player as claimed in claim 2, wherein the earphone includes an electric cable connected to the plug and extending out from inside the lid, with a seal located between the cable and the lid.

15. The waterproof audio player as claimed in claim 14, wherein the seal comprises glue.

16. The waterproof audio player as claimed in claim 2, wherein the electrical plug includes a base having a first end from which the electrical connector projects through the inner wall of the lid and a second end located by an internal fixture of the lid.

17. The waterproof audio player as claimed in claim 2, including a securing member which extends through the lid and engages a part of the casing to secure the lid when closing the casing.

18. The waterproof audio player as claimed in claim 17, wherein the securing member comprises one of a screw and a bolt and the part of the casing comprises a nut.

19. The waterproof audio player as claimed in claim 17, wherein the lid has a central axis along which the securing member extends.

20. The waterproof audio player as claimed in claim 17, wherein the securing member extends substantially parallel to the electrical connector.
